(19) United States
(12) Patent Application Publication
(10) Pub. No.: US 2026/0066905 A1
(43) Pub. Date: Mar. 5, 2026

(54) Method and System for Redundancy Switch Between Two Controllers for Supplementary Damping of Governor

(71) Applicant: Guizhou Power Grid Co., Ltd., Guiyang (CN)

(72) Inventors: Qinfeng MA, Guiyang (CN); Su AN, Guiyang (CN); Junqiu FAN, Guiyang (CN); Qingxin PU, Guiyang (CN); Mingshun LIU, Guiyang (CN); Qingqing ZHANG, Guiyang (CN); Lingzi ZHU, Guiyang (CN); Jie CAO, Guiyang (CN); Rui CHEN, Guiyang (CN); Junquan CHEN, Guiyang (CN); Zhibang WANG, Guiyang (CN); Fu YANG, Guiyang (CN); Zhongrun XIE, Guiyang (CN); Yixin CHEN, Guiyang (CN); Chuanmei ZHOU, Guiyang (CN); Yingshuang WU, Guiyang (CN); Guosong WANG, Guiyang (CN); Xiang FAN, Guiyang (CN)

(21) Appl. No.: 19/011,301

(22) Filed: Jan. 6, 2025

(30) Foreign Application Priority Data
Aug. 28, 2024 (CN) 2024111917925

(51) Int. Cl. H03K 19/17756; G06F 8/40; H03K 19/17764

(52) U.S. Cl. CPC H03K 19/17756; G06F 8/40; H03K 19/17764

(57) ABSTRACT

Disclosed are a method and system for redundancy switch between two controllers for supplementary damping of a governor, relating to the technical field of control methods. The method includes acquiring a participation condition according to an output result, listing the participation condition in a truth value table and supplementing correlation logic; outputting the correlation logic as an image language, and simplifying the image language; and acquiring switch logic by a simplified image language, and transforming the switch logic into a programming language of the controller. A complex control relation can be decomposed in the disclosure, so that the difficulty can be reduced, and a correct and comprehensive control purpose can be achieved. Moreover, the method has universality.

### CROSS-REFERENCE TO RELATED APPLICATIONS

The present application claims priority to Chinese Patent Application No. 2024111917925, filed on Aug. 28, 2024, the entire disclosure of which is incorporated herein by reference.

### TECHNICAL FIELD

The disclosure relates to the technical field of control methods, and in particular to a method and system for redundancy switch between two controllers for supplementary damping of a governor.

### BACKGROUND

For a variety of important control apparatuses in a power industry, it is common practice to configure two controllers, with the attempt to enhance overall reliability of a system. In terms of supplementary damping control of a governor of a hydraulic turbine, for a single unit of 200,000 kW or higher, its electrical control system is subject to redundancy configuration relying primarily on two controllers. When one controller has a fault, switch to a standby controller is conducted automatically according to designed switch logic, so that supplementary damping control of a governing system can still work normally. Thus, the reliability and stability of the system are enhanced.

In this case, redundancy switch between the controllers takes a significant role. It is of great importance to make the switch logic correct and rational. The rational switch logic depends on comprehensive design by off-line engineers. After the design is completed, how to accurately realize programming with a scientific means is still to be addressed.

The governing system of the hydraulic turbine is required to have a controller switch function. The methods used vary with manufacturers. There are two primary ways to employ signals, one is to use hard wiring for information exchange, and the other one is to use a communication bus for information exchange.

Implementation carriers are also divided into two types, one is to use a third-party programmable logic controller (PLC) as an arbitration unit that carries the switch logic, as shown in FIG. 1 of the description, and the other one is to write the switch logic in two sets of controls separately for autonomous selection, as shown in FIG. 2 of the description.

Numbers of specifically-collected signals vary with the apparatus manufacturers. However, on the basis of overall analysis, indispensable fault information and states include a general fault, a serious fault, a crash fault, handle selection, etc. The programming difficulty is low if a few conditions are involved in logic determination, while the difficulty will be increased exponentially when a large number of conditions are involved in logic determination. Without a scientific method, it is inevitable to neglect the conditions only by experience.

### SUMMARY

In view of the problems in an existing method and system for redundancy switch between two controllers for supplementary damping of a governor, the disclosure is provided.

Thus, the problem to be solved by the disclosure is that when a large number of conditions are involved in logic determination, neglect is likely to be caused, resulting in a switch failure of the controllers.

In order to solve the above technical problems, the disclosure provides the technical solution as follows:

In a first aspect, a method for redundancy switch between two controllers for supplementary damping of a governor is provided in an example of the disclosure. The method includes:

acquiring a corresponding participation condition according to an output result, listing the corresponding participation condition and the output result in a truth value table, and supplementing correlation logic between the participation condition and the output result;
outputting the correlation logic as an image language, and simplifying the image language output; and
acquiring switch logic by means of a simplified image language, and transforming, according to a controller language, the switch logic into a programming language corresponding to the controller language.

As a preferred solution of the method for redundancy switch between two controllers for supplementary damping of a governor of the disclosure, when the participation condition and the output result are listed in the truth value table, the method specifically includes:
acquiring a type number A of the participation condition, and creating a truth value table having a column number A+1 according to the type number A;
acquiring a logic frequency B of the participation condition and the output result, and creating a truth value table having a row number B+1 according to the logic frequency B;
filling the truth value table with the correlation logic, and determining whether the correlation logic for filling is absent;
making no response in a case that a determination result is that the correlation logic is not absent; and
reacquiring the correlation logic according to an actual position, and filling a vacant position with the correlation logic in a case that a determination result is that the correlation logic is absent.

As a preferred solution of the method for redundancy switch between two controllers for supplementary damping of a governor of the disclosure, when the correlation logic is output as the image language, the method specifically includes:
creating a logic line segment having a same number as the logic frequency B;
setting logic entries having a same number as the type number A in each logic line segment, and writing the logic entries in sequence according to the truth value table; and
acquiring the image language with output ends of all the logic line segments as the output results.

As a preferred solution of the method for redundancy switch between two controllers for supplementary damping of a governor of the disclosure, the simplifying the image language includes a first simplification mode and a second simplification mode;
a simplification method in the first simplification mode includes:
selecting any two logic line segments having a same output result; determining whether corresponding logic entries in the two logic line segments having a same output result are absent; reselecting two new logic line segments having a same output result in a case that a determination result is that the corresponding logic entries are not absent, where the new logic line segments are not completely identical to old logic line segments; and performing a first supplementary simplification in a case that a determination result is that the corresponding logic entries are absent;
the first supplementary simplification includes:
acquiring the absent logic entries; determining whether two logic entries before and after the absent logic entries are identical to each other; if not, reselecting two new logic line segments having a same output result, where the new logic line segments are not completely identical to old logic line segment; and if yes, performing a first final simplification; and
the first final simplification includes:
connecting a front end and a rear end of the absent logic entries, so as to connect the two logic line segments; removing an identical logic entry from one logic line segment, then removing the absent logic entries, and finally outputting new logic line segments; and reselecting two new logic line segments having a same output result, where the new logic line segments are not completely identical to old logic line segments.

As a preferred solution of the method for redundancy switch between two controllers for supplementary damping of a governor of the disclosure, a simplification method in the second simplification mode includes:
selecting any two logic line segments having a same output result; determining whether one or more corresponding logic entries in the two logic line segments are identical to each other; reselecting two new logic line segments having a same output result in a case that a determination result is that the one or more corresponding logic entries are not identical to each other, where the new logic line segments are not completely identical to old logic line segments; and performing a second supplementary simplification in a case that a determination result is that the one or more corresponding logic entries are identical to each other;
the second supplementary simplification includes:
taking the one or more logic entries as a whole; determining whether two logic entries after the whole in the two logic line segments are opposite to each other; reselecting two new logic line segments having a same output result in a case that a determination result is that the two logic entries are not opposite to each other, where the new logic line segments are not completely identical to old logic line segments; and performing a second final simplification in a case that a determination result is that the two logic entries are opposite to each other; and
the second final simplification includes:
connecting one end after the whole, so as to connect the two logic line segments; removing the logic entries taken as the whole from one logic line segment, then removing the opposite logic entries, and finally outputting new logic line segments; and reselecting two new logic line segments having a same output result, where the new logic line segments are not completely identical to old logic line segments.

As a preferred solution of the method for redundancy switch between two controllers for supplementary damping of a governor of the disclosure, the acquiring switch logic by means of a simplified image language includes:
acquiring a number of the logic line segments, and solving a number of pieces of the switch logic according to a number of the logic entries;
interpreting the logic entries in the logic line segments in sequence in a forward direction, and recording interpretation results in corresponding switch logic; and
interpreting the logic entries in the logic line segments in sequence in a backward direction, and recording interpretation results in corresponding switch logic; where
the switch logic is in a Chinese character mode.

As a preferred solution of the method for redundancy switch between two controllers for supplementary damping of a governor of the disclosure, after acquired, the switch logic undergoes cloud storage, and a cloud storage system generates a corresponding key for encryption.

In a second aspect, a system for redundancy switch between two controllers for supplementary damping of a governor is provided in an example of the disclosure. The system includes: a truth value table generation module, an information simplification module, and a switch logic output module; where
the truth value table generation module is configured to generate a truth value table according to output results and participation conditions, display the output results under different input conditions, analyze logic relations between the participation conditions and the output results, and supplement correlation logic of these conditions;
the information simplification module is configured to simplify an image language, so as to make the image language more concise and clear, and convenient to understand and implement; and
the switch logic output module is configured to generate switch logic, and enable the switch logic to be transformed into programming codes in different controller languages.

In a third aspect, a computer apparatus is provided in an example of the disclosure. The computer apparatus includes a memory and a processor, where the memory stores a computer program, and the processor implements any step of the above method for redundancy switch between two controllers for supplementary damping of a governor when executing the computer program.

In a fourth aspect, a computer-readable storage medium is provided in an example of the disclosure. The computer-readable storage medium stores a computer program, where the computer program implements any step of the above method for redundancy switch between two controllers for supplementary damping of a governor when executed by a processor.

The disclosure has the beneficial effects as follows: based on a truth value table method, the solution provides a universal method independent of technical capacities of humans for a complex switch logic task to be programmed. According to the steps provided in the method, a complex control switch relation can be decomposed, so that the difficulty can be reduced, and a correct and comprehensive control purpose can be achieved. Moreover, the method has universality to deal with similar problems, such as a control circuit of a switching number input and output relation, and thus can be popularized and applied to electrical control and programming in a wide range as a tool.

### BRIEF DESCRIPTION OF DRAWINGS

In order to describe the technical solution in examples of the disclosure more clearly, a brief description of the accompanying drawings required for describing the examples will be provided below. Obviously, the accompanying drawings in the following description show merely some examples of the disclosure. Those of ordinary skill in the art can also derive other accompanying drawings from these accompanying drawings without creative efforts. Specifically:

FIG. 1 is a schematic diagram of redundancy switch in the presence of a third-party arbitration unit in the prior art;

FIG. 2 is a schematic diagram of redundancy switch in the absence of a third-party arbitration unit in the prior art;

FIG. 3 is a flowchart of a method for redundancy switch between two controllers for supplementary damping of a governor;

FIG. 4 is a diagram of an unsimplified image language of a method for redundancy switch between two controllers for supplementary damping of a governor;

FIG. 5 is a first illustrative diagram of a first simplification mode of a method for redundancy switch between two controllers for supplementary damping of a governor;

FIG. 6 is a second illustrative diagram of a first simplification mode of a method for redundancy switch between two controllers for supplementary damping of a governor;

FIG. 7 is a third illustrative diagram of a first simplification mode of a method for redundancy switch between two controllers for supplementary damping of a governor;

FIG. 8 is a first illustrative diagram of a second simplification mode of a method for redundancy switch between two controllers for supplementary damping of a governor;

FIG. 9 is a second illustrative diagram of a second simplification mode of a method for redundancy switch between two controllers for supplementary damping of a governor;

FIG. 10 is a third illustrative diagram of a second simplification mode of a method for redundancy switch between two controllers for supplementary damping of a governor;

FIG. 11 is a fourth illustrative diagram of a second simplification mode of a method for redundancy switch between two controllers for supplementary damping of a governor;

FIG. 12 is a diagram of a simplified image language of a method for redundancy switch between two controllers for supplementary damping of a governor;

FIG. 13 is an illustrative diagram of an image language of a method for redundancy switch between two controllers for supplementary damping of a governor;

FIG. 14 is a schematic diagram of switch logic of a method for redundancy switch between two controllers for supplementary damping of a governor;

FIG. 15 is a diagram of a circuit of a hydraulic system of a governor of a method for redundancy switch between two controllers for supplementary damping of a governor; and

FIG. 16 is a diagram of electrical control of a hydraulic system of a governor of a method for redundancy switch between two controllers for supplementary damping of a governor.

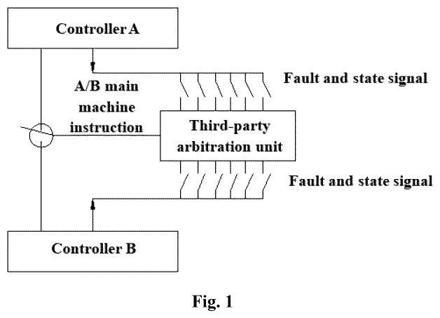

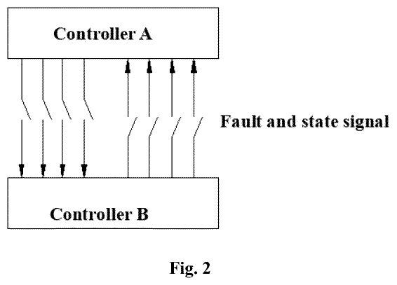

### DETAILED DESCRIPTION OF THE EMBODIMENTS

In order to make the above objectives, features, and advantages of the disclosure clearer and more understandable, particular embodiments of the disclosure will be described in detail below in conjunction with the drawings of the description. Apparently, examples described are some examples rather than all examples of the disclosure. Based on the examples of the disclosure, all other examples derived by those of ordinary skill in the art without creative efforts should fall within the scope of protection of the disclosure.

In the following description, various specific details are set forth to facilitate thorough understanding of the disclosure. However, the disclosure can also be implemented in other ways than those described herein. Those skilled in the art can make similar popularization without departing from the essence of the disclosure. Thus, the disclosure is not limited by specific examples disclosed below.

Secondly, “an example” or “example” mentioned herein means a particular feature, structure, or characteristic that can be included in at least one embodiment of the disclosure. The phase “in an example” at different places in the description neither indicates a same example, nor is a separate or selective example mutually exclusive of other examples.

The disclosure will be described in detail with reference to the schematic drawings. When the examples of the disclosure are described in detail, for ease of description, the sectional views showing device structures will be enlarged partially without following a general ratio. The schematic diagrams are merely illustrative, and should not limit the scope of protection of the disclosure herein. In addition, in actual production, the three-dimensional space sizes including the length, width, and depth should be included.

Moreover, in the description of the disclosure, it should be noted that the orientation or position relations indicated by the terms “upper, lower, internal, and external” etc. are based on the orientation or position relations shown in the accompanying drawings, are merely for facilitating the description of the disclosure and simplifying the description, rather than indicating or implying that the device or element referred to must have a particular orientation or be constructed and operated in a particular orientation, and thus cannot be interpreted as limiting the disclosure. In addition, the term “first, second, or third” is merely for description, and cannot be interpreted as indicating or implying relative importance.

In the disclosure, the terms “mount, connected, and connection” should be understood in a broad sense. For example, they can denote a fixed connection, a detachable connection, an integrated connection, a mechanical connection, an electrical connection, a direct connection, an indirect connection via an intermediate medium, or communication inside two elements, unless explicitly specified and defined otherwise. For those of ordinary skill in the art, the specific meanings of the above terms in the disclosure can be understood according to specific circumstances.

### Example 1

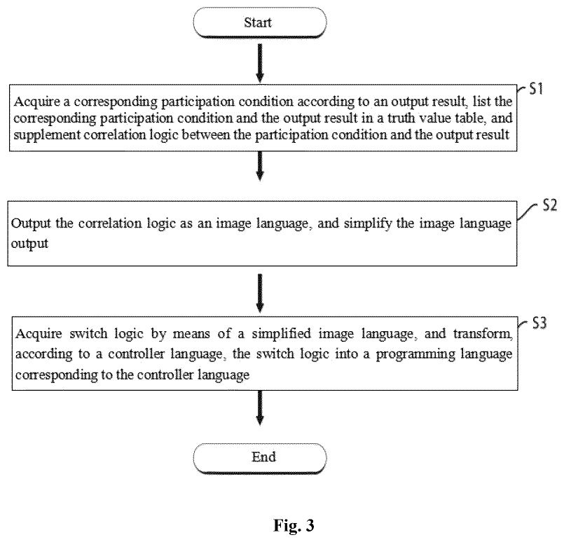

With reference to FIGS. 3-14, a method for redundancy switch between two controllers for supplementary damping of a governor according to a first example of the disclosure is shown. The method includes:
S1, a corresponding participation condition is acquired according to an output result, the corresponding participation condition and the output result are listed in a truth value table, and correlation logic between the participation condition and the output result is supplemented.

When the participation condition and the output result are listed in the truth value table, the method specifically includes:
a type number A of the participation condition is acquired, and a truth value table having a column number A+1 is created according to the type number A;
a logic frequency B of the participation condition and the output result is acquired, and a truth value table having a row number B+1 is created according to the logic frequency B;
the truth value table is filled with the correlation logic, and whether the correlation logic for filling is absent is determined;
no response is made in a case that a determination result is that the correlation logic is not absent; and
the correlation logic is reacquired according to an actual position, and a vacant position is filled with the correlation logic in a case that a determination result is that the correlation logic is absent.

When the truth value table is generated specifically, for example, types of the participation conditions are divided into a heartbeat fault, an opposite-side major fault, a main machine button, a self major fault, an opposite-side main machine return, and an output main machine condition, and the type number equals 6. Thus, the column number of the truth value table output is set to 7, and an extra column is set for serial numbers.

The logic frequency B acquired has 18 cases. Thus, the row number of the truth value table output is set to 19, and an extra row is set for a content. All the participation conditions are listed in the truth value table, and each row is filled with an output result and logic entry of one condition, as specifically shown in Table 1.

TABLE 1
Truth Value Table of Fault Switch Condition

| | | Opposite- | | | Opposite- | Output |
|---|---|---|---|---|---|---|
| | | side | Main | Self | side main | main |
| Serial | Heartbeat | major | machine | major | machine | machine |
| number | fault | fault | button | fault | return | condition |
| 1 | 0 | 0 | 0 | 0 | 0 | 1 |
| 2 | 0 | 0 | 0 | 0 | 1 | 0 |
| 3 | 0 | 0 | 0 | 1 | 0 | 0 |
| 4 | 0 | 0 | 0 | 1 | 1 | 0 |
| 5 | 0 | 0 | 1 | 0 | 0 | 1 |
| 6 | 0 | 0 | 1 | 0 | 1 | 1 |
| 7 | 0 | 0 | 1 | 1 | 0 | 0 |
| 8 | 0 | 0 | 1 | 1 | 1 | 0 |
| 9 | 0 | 1 | 0 | 0 | 0 | 1 |
| 10 | 0 | 1 | 0 | 0 | 1 | 1 |
| 11 | 0 | 1 | 0 | 1 | 0 | 1 |
| 12 | 0 | 1 | 0 | 1 | 1 | 0 |
| 13 | 0 | 1 | 1 | 0 | 0 | 1 |
| 14 | 0 | 1 | 1 | 0 | 1 | 1 |
| 15 | 0 | 1 | 1 | 1 | 0 | 1 |
| 16 | 0 | 1 | 1 | 1 | 1 | 1 |
| 17 | 1 | / | / | / | / | 1 |
| 18 | 0 | / | / | / | / | 0 |

In actual operation, for example, in heartbeat detection, 1 denotes a fault, and 0 denotes a normal condition.

S2, the correlation logic is output as an image language, and the image language output is simplified.

When the correlation logic is output as the image language, the method specifically includes:
a logic line segment having a same number as the logic frequency B is created;
logic entries having a same number as the type number A are set in each logic line segment, and the logic entries are written in sequence according to the truth value table; and
the image language is acquired with output ends of all the logic line segments as the output results.

At first, the logic frequency B equals 18. Thus, 18 logic line segments are created. Moreover, the type number A equals 6, so that 6 logic entries are created in each logic line segment.

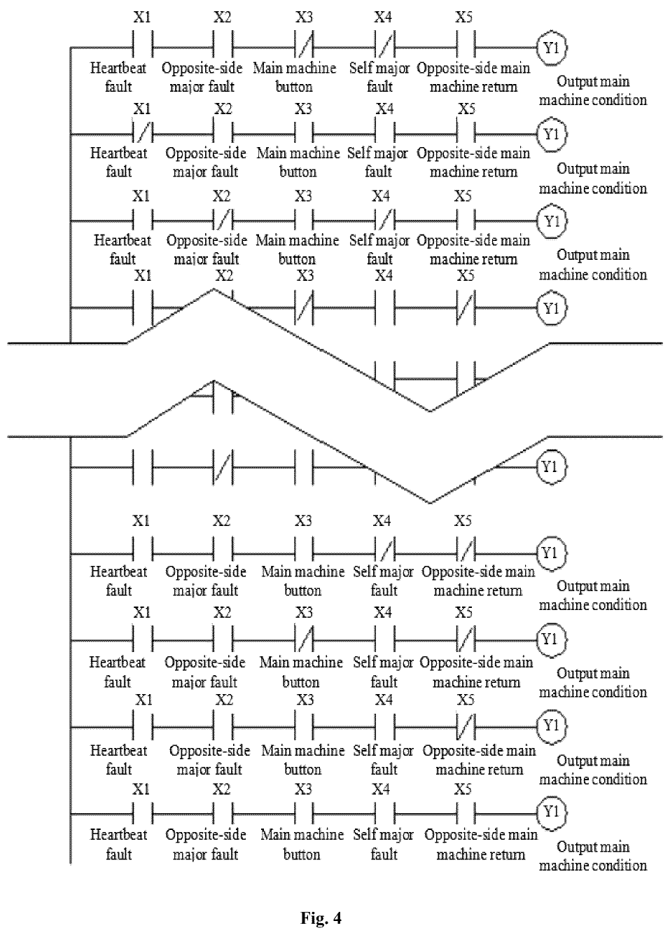

During specific creation, as shown in FIG. 4, the logic frequency B is determined at first, then the logic line segments are created, and the logic line segments are ended with the output results. In this case, the output results are the output main machine conditions.

The step that the image language is simplified includes a first simplification mode and a second simplification mode;
a simplification method in the first simplification mode includes:
any two logic line segments having a same output result are selected; whether corresponding logic entries in the two logic line segments having a same output result are absent is determined; two new logic line segments having a same output result are reselected in a case that a determination result is that the corresponding logic entries are not absent, where the new logic line segments are not completely identical to old logic line segments; and a first supplementary simplification is performed in a case that a determination result is that the corresponding logic entries are absent;
the first supplementary simplification includes:
the absent logic entries are acquired; whether two logic entries before and after the absent logic entries are identical to each other is determined; if not, two new logic line segments having a same output result are reselected, where the new logic line segments are not completely identical to old logic line segment; and if yes, a first final simplification is performed; and the first final simplification includes:
a front end and a rear end of the absent logic entries are connected,
so as to connect the two logic line segments; an identical logic entry is removed from one logic line segment, then the absent logic entries are removed, and finally new logic line segments are output; and two new logic line segments having a same output result are reselected, where the new logic line segments are not completely identical to old logic line segments.

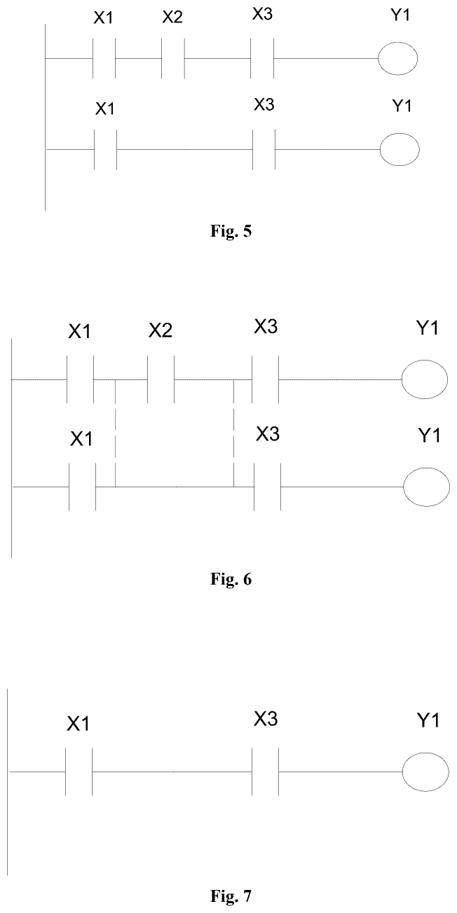

For example, when simplification is performed in this case, the schematic diagram before simplification is shown in FIG. 5, where Y1 denotes the output result. By simplifying the logic, the logic entries before and after each identical logic entry (X2) may be connected linearly. As shown in FIG. 6, the logic entry (X2) is connected in parallel to a wire section, which is similar to being shorted. Thus, the logic entry (X2) is invalid, and FIG. 7 shows a condition after transformation.

A simplification method in the second simplification mode includes:
any two logic line segments having a same output result are selected; whether one or more corresponding logic entries in the two logic line segments are identical to each other is determined; two new logic line segments having a same output result are reselected in a case that a determination result is that the one or more corresponding logic entries are not identical to each other, where the new logic line segments are not completely identical to old logic line segments; and a second supplementary simplification is performed in a case that a determination result is that the one or more corresponding logic entries are identical to each other;
the second supplementary simplification includes:
the one or more logic entries are taken as a whole; whether two logic entries after the whole in the two logic line segments are opposite to each other is determined; two new logic line segments having a same output result are reselected in a case that a determination result is that the two logic entries are not opposite to each other, where the new logic line segments are not completely identical to old logic line segments; and a second final simplification is performed in a case that a determination result is that the two logic entries are opposite to each other; and
the second final simplification includes:
one end after the whole is connected, so as to connect the two logic line segments; the logic entries taken as the whole are removed from one logic line segment, then the opposite logic entries are removed, and finally new logic line segments are output; and two new logic line segments having a same output result are reselected, where the new logic line segments are not completely identical to old logic line segments.

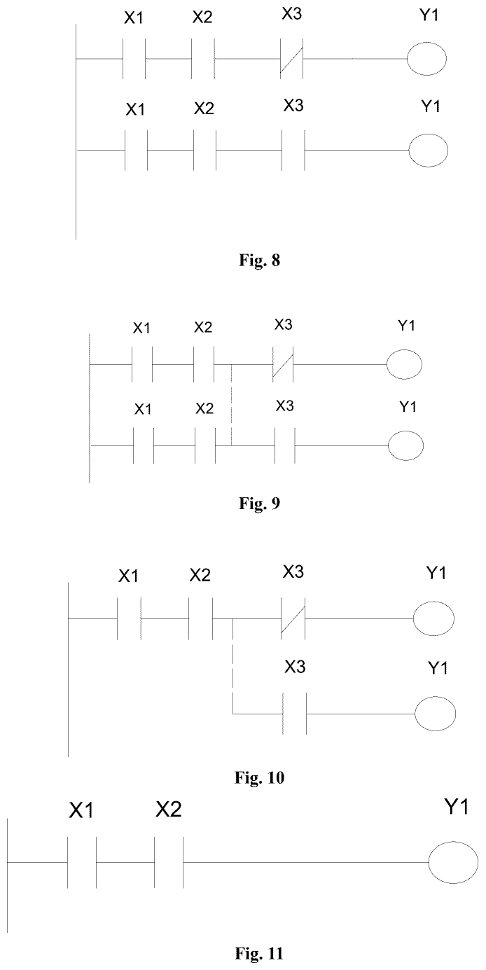

For example, when simplification is performed in this case, the schematic diagram before simplification is shown in FIG. 8, where Y1 denotes the output result. By simplifying the logic, the logic entry (X1) and the logic entry (X2) are taken as a whole, so that connection is made after the whole (i.e. after X2), as shown in FIG. 9. As shown in FIG. 10, the identical conditions (X1 and X2) are connected in parallel for removal and simplification. Regardless of whether the logic entry (X3)=1 or the logic entry (X3)=0, both the logic entry (X1) and the logic entry (X2) can drive the output result (Y1), so that the logic entry (X3) is removed, as shown in FIG. 11.

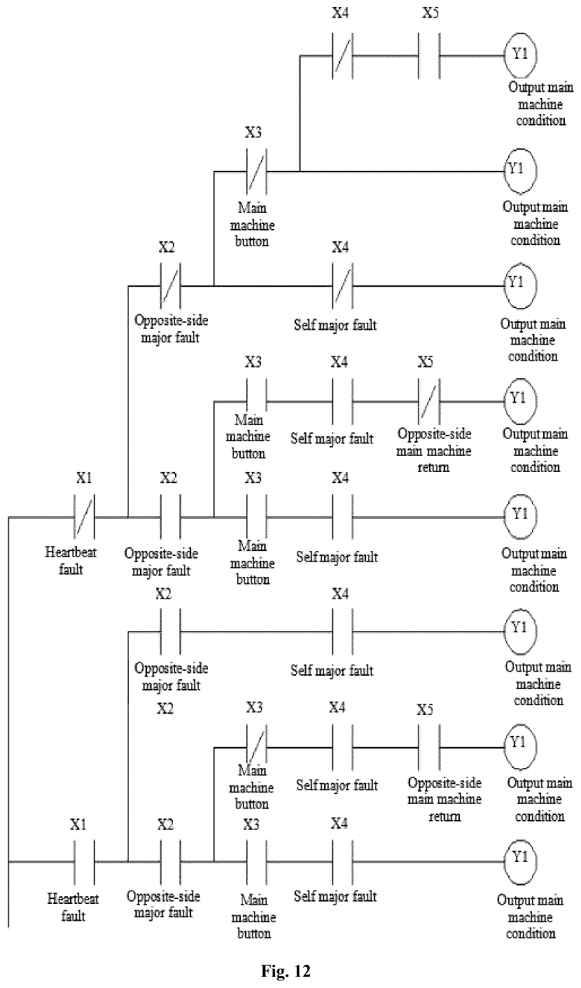

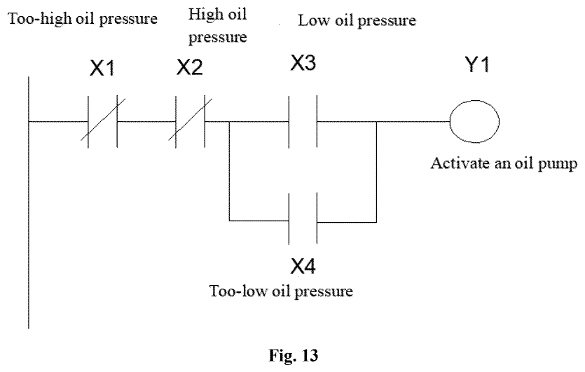

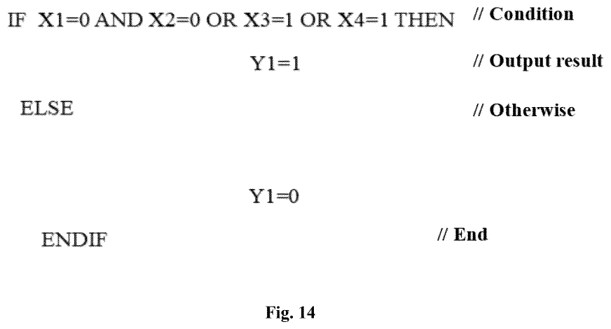

On the basis of the above simplification steps, FIG. 4 is simplified, and reference is made to FIG. 12 for a simplified figure.

S3, switch logic is acquired by means of a simplified image language, and according to a controller language, the switch logic is transformed into a programming language corresponding to the controller language.

The step that switch logic is acquired by means of a simplified image language includes:
a number of the logic line segments is acquired, and a number of pieces of the switch logic is solved according to a number of the logic entries;
the logic entries in the logic line segments are interpreted in sequence in a forward direction, and interpretation results are recorded in corresponding switch logic; and
the logic entries in the logic line segments are interpreted in sequence in a backward direction, and interpretation results are recorded in corresponding switch logic; where
the switch logic is in a Chinese character mode.

For example, as shown in FIG. 13, according to an oil pressure, a piece of logic of an oil pump is activated, and a state of Y is determined through on/off of a signal X. A content after interpretation is as follows: when a too-high oil pressure signal and a high oil pressure signal have not arrived, and a low oil pressure signal or a too-low oil pressure signal has arrived, the oil pump starts to be activated. In other words, X1=0, X2=0, X3=1 or X3=0, and Y1=1 is output.

For another example in a backward direction, if a too-high oil pressure signal or a high oil pressure signal has arrived, a circuit is disconnected, and the oil pump will not be activated. Regardless of whether the low oil pressure and the too-low oil pressure have arrived, the oil pump will not be activated.

When the logic is transplanted into the controller, such as a visual basic (VB) language or a structured text (ST) language, an interpretation result is shown in FIG. 14.

After acquired, the switch logic undergoes cloud storage, and a cloud storage system generates a corresponding key for encryption.

In conclusion, based on a truth value table method, the solution provides a universal method independent of technical capacities of humans for a complex switch logic task to be programmed. According to the steps provided in the method, a complex control switch relation can be decomposed, so that the difficulty can be reduced, and a correct and comprehensive control purpose can be achieved. Moreover, the method has universality to deal with similar problems, such as a control circuit of a switching number input and output relation, and thus can be popularized and applied to electrical control and programming in a wide range as a tool.

### Example 2

On the basis of the first example, a system for redundancy switch between two controllers for supplementary damping of a governor is further provided in the example. The system includes a truth value table generation module, an information simplification module, and a switch logic output module; where
the truth value table generation module is configured to generate a truth value table according to output results and participation conditions, display the output results under different input conditions, analyze logic relations between the participation conditions and the output results, and supplement correlation logic of these conditions;
the information simplification module is configured to simplify an image language, so as to make the image language more concise and clear, and convenient to understand and implement; and
the switch logic output module is configured to generate switch logic, and enable the switch logic to be transformed into programming codes in different controller languages.

A computer apparatus is further provided in the example. The computer apparatus is suitable for the method for redundancy switch between two controllers for supplementary damping of a governor, and includes a memory and a processor, where the memory is configured to store a computer-executable instruction, and the processor is configured to execute the computer-executable instruction, so as to implement the method for redundancy switch between two controllers for supplementary damping of a governor according to the above example.

The computer apparatus can be a terminal, and include a processor, a memory, a communication interface, a display screen, and an input device that are connected by means of a system bus. The processor of the computer apparatus is configured to provide calculation and control capacities. The memory of the computer apparatus includes a non-volatile storage medium and an internal memory. The non-volatile storage medium stores an operation system and a computer program. The internal memory provides a running environment for the operation system and the computer program in the non-volatile storage medium. The communication interface of the computer apparatus is configured to communicate with an external terminal in a wired or wireless manner. The wireless manner can be implemented through wireless fidelity (WIFI), an operator network, near field communication (NFC), etc. The display screen of the computer apparatus can be a liquid crystal display screen or an electronic ink display screen. The input device of the computer apparatus can be a touch layer covering the display screen, a key, a trackball, or a touch pad arranged on a housing of the computer apparatus, or an external keyboard, touch pad, or mouse.

A storage medium is further provided in the example. The storage medium stores a computer program, where the computer program implements the method for redundancy switch between two controllers for supplementary damping of a governor according to the above example when executed by a processor.

The storage medium according to the example and the data storage method according to the above example belong to the same inventive concept, so that reference can be made to the above example for the technical details not described in detail in the example, and the example and the above example have the same beneficial effects.

### Example 3

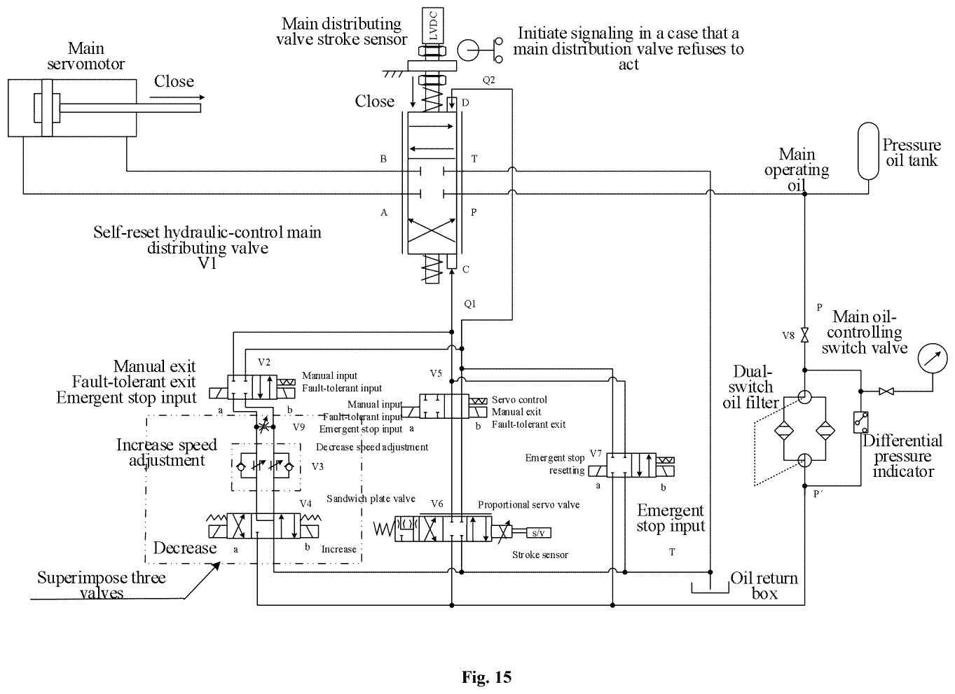

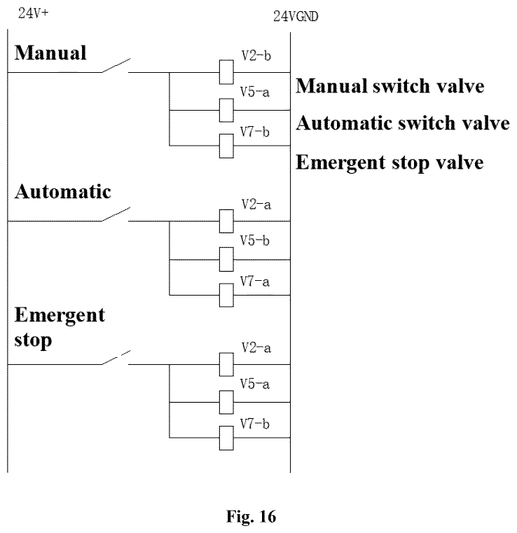

With reference to FIGS. 15 and 16, on the basis of the two previous examples, a method for redundancy switch between two controllers for supplementary damping of a governor is provided in the example, and an instance is further provided.

A diagram of a hydraulic principle of a main distributing valve of the governor is shown in FIG. 15. A manual operation, an automatic operation, and an emergent stop operation that are mutually locked are realized. Since any one of 1 and 0 that are mutually exclusive indicates a position of a valve element of a solenoid valve, a relation can be determined according to the manual operation, the automatic operation, and the emergent stop operation.

According to the functional demands on components of a hydraulic valve group, the method provided in the patent can be employed in a case that a diagram of an electrical principle is designed to drive coils of the solenoid valve. In other words, a truth value table method is applied to the design. At first, with three functional demands as the target, electrical control objects (the coils of the solenoid valve) are listed.

TABLE 2
List of Solenoid Coils For Distributing Valve Group

| Serial | | | | | | | |
|---|---|---|---|---|---|---|---|
| number | V2-a | V2-b | V5-a | V5-b | V7-a | V7-b | State |
| 1 | 0 | 1 | 1 | 0 | 1 | 0 | Manual |
| 2 | 1 | 0 | 0 | 1 | 1 | 0 | Automatic |
| 3 | 1 | 0 | 1 | 0 | 0 | 1 | Emergent |
| | | | | | | | stop |

In Table 2, 1 denotes pulse, and an image language can be output on the basis of the table, as shown in FIG. 16.

It should be noted that the above examples are merely used to explain the technical solution of the disclosure, and are not intended to limit the disclosure. Although the disclosure is described in detail with reference to the preferred examples, those of ordinary skill in the art should understand that they can make modifications or equivalent substitutions to the technical solution of the disclosure without departing from the spirit and scope of the technical solution of the disclosure. These modifications or equivalent substitutions should fall within the scope of the claims of the disclosure.

What is claimed is:

1. A method for redundancy switch between two controllers for supplementary damping of a governor, comprising:
acquiring a corresponding participation condition according to an output result, listing the corresponding participation condition and the output result in a truth value table, and supplementing correlation logic between the participation condition and the output result;
outputting the correlation logic as an image language, and simplifying the image language output; and
acquiring switch logic by means of a simplified image language, and transforming, according to a controller language, the switch logic into a programming language corresponding to the controller language.

2. The method for redundancy switch between two controllers for supplementary damping of a governor according to claim 1, wherein when the participation condition and the output result are listed in the truth value table, the method specifically comprises:
acquiring a type number A of the participation condition, and creating a truth value table having a column number A+1 according to the type number A;
acquiring a logic frequency B of the participation condition and the output result, and creating a truth value table having a row number B+1 according to the logic frequency B;
filling the truth value table with the correlation logic, and determining whether the correlation logic for filling is absent;
making no response in a case that a determination result is that the correlation logic is not absent; and
reacquiring the correlation logic according to an actual position, and filling a vacant position with the correlation logic in a case that a determination result is that the correlation logic is absent.

3. The method for redundancy switch between two controllers for supplementary damping of a governor according to claim 2, wherein when the correlation logic is output as the image language, the method specifically comprises:
creating a logic line segment having a same number as the logic frequency B;
setting logic entries having a same number as the type number A in each logic line segment, and writing the logic entries in sequence according to the truth value table; and
acquiring the image language with output ends of all the logic line segments as the output results.

4. The method for redundancy switch between two controllers for supplementary damping of a governor according to claim 3, wherein the simplifying the image language comprises a first simplification mode and a second simplification mode;
a simplification method in the first simplification mode comprises:
selecting any two logic line segments having a same output result; determining whether corresponding logic entries in the two logic line segments having a same output result are absent; reselecting two new logic line segments having a same output result in a case that a determination result is that the corresponding logic entries are not absent, wherein the new logic line segments are not completely identical to old logic line segments; and performing a first supplementary simplification in a case that a determination result is that the corresponding logic entries are absent;
the first supplementary simplification comprises:
acquiring the absent logic entries; determining whether two logic entries before and after the absent logic entries are identical to each other; if not, reselecting two new logic line segments having a same output result, wherein the new logic line segments are not completely identical to old logic line segment; and if yes, performing a first final simplification; and
the first final simplification comprises:
connecting a front end and a rear end of the absent logic entries, so as to connect the two logic line segments; removing an identical logic entry from one logic line segment, then removing the absent logic entries, and finally outputting new logic line segments; and reselecting two new logic line segments having a same output result, wherein the new logic line segments are not completely identical to old logic line segments.

5. The method for redundancy switch between two controllers for supplementary damping of a governor according to claim 4, wherein a simplification method in the second simplification mode comprises:
selecting any two logic line segments having a same output result; determining whether one or more corresponding logic entries in the two logic line segments are identical to each other; reselecting two new logic line segments having a same output result in a case that a determination result is that the one or more corresponding logic entries are not identical to each other, wherein the new logic line segments are not completely identical to old logic line segments; and performing a second supplementary simplification in a case that a determination result is that the one or more corresponding logic entries are identical to each other;
the second supplementary simplification comprises:
taking the one or more logic entries as a whole; determining whether two logic entries after the whole in the two logic line segments are opposite to each other; reselecting two new logic line segments having a same output result in a case that a determination result is that the two logic entries are not opposite to each other, wherein the new logic line segments are not completely identical to old logic line segments; and performing a second final simplification in a case that a determination result is that the two logic entries are opposite to each other; and
the second final simplification comprises:
connecting one end after the whole, so as to connect the two logic line segments; removing the logic entries taken as the whole from one logic line segment, then removing the opposite logic entries, and finally outputting new logic line segments; and reselecting two new logic line segments having a same output result, wherein the new logic line segments are not completely identical to old logic line segments.

6. The method for redundancy switch between two controllers for supplementary damping of a governor according to claim 5, wherein the acquiring switch logic by means of a simplified image language comprises:
acquiring a number of the logic line segments, and solving a number of pieces of the switch logic according to a number of the logic entries;
interpreting the logic entries in the logic line segments in sequence in a forward direction, and recording interpretation results in corresponding switch logic; and
interpreting the logic entries in the logic line segments in sequence in a backward direction, and recording interpretation results in corresponding switch logic; wherein
the switch logic is in a Chinese character mode.

7. The method for redundancy switch between two controllers for supplementary damping of a governor according to claim 6, wherein after acquired, the switch logic undergoes cloud storage, and a cloud storage system generates a corresponding key for encryption.

8. A system for redundancy switch between two controllers for supplementary damping of a governor, based on the method for redundancy switch between two controllers for supplementary damping of a governor according to claim 1, comprising a truth value table generation module, an information simplification module, and a switch logic output module; wherein
the truth value table generation module is configured to generate a truth value table according to output results and participation conditions, display the output results under different input conditions, analyze logic relations between the participation conditions and the output results, and supplement correlation logic of these conditions;
the information simplification module is configured to simplify an image language, so as to make the image language more concise and clearer, and convenient to understand and implement; and
the switch logic output module is configured to generate switch logic, and enable the switch logic to be transformed into programming codes in different controller languages.

9. A computer apparatus, comprising a memory and a processor, wherein the memory stores a computer program, and the processor implements steps of the method for redundancy switch between two controllers for supplementary damping of a governor according to claim 1 when executing the computer program.

10. A computer-readable storage medium, storing a computer program, wherein the computer program implements steps of the method for redundancy switch between two controllers for supplementary damping of a governor according to claim 1 when executed by a processor.
